(19) United States
(12) Patent Application Publication
(10) Pub. No.: US 2014/0055019 A1
(43) Pub. Date: Feb. 27, 2014

(54) LOW PROFILE HINGE AND PIN MOUNT

(71) Applicants: Andriy PLETENETSKYY, Sunnyvale, CA (US); Tang Yew Tan, San Francisco, CA (US); David A. Pakula, San Francisco, CA (US)

(72) Inventors: Andriy PLETENETSKYY, Sunnyvale, CA (US); Tang Yew Tan, San Francisco, CA (US); David A. Pakula, San Francisco, CA (US)

(73) Assignee: Apple Inc., Cupertino, CA (US)

(21) Appl. No.: 13/592,240

(22) Filed: Aug. 22, 2012

(51) Int. Cl. H05K 7/16; B23P 11/00

(52) U.S. Cl. 312/326; 248/288.11; 29/525.01

(57) ABSTRACT

Described embodiments provide a low profile hinge and pin mount to be mounted within a small encasement. The mount has a low profile and takes up minimal space within the small encasement without sacrificing structural support for a component and external forces placed on the mount. The mount includes a bracket, a pin and a fastener. The bracket includes a rounded end, a fastening end and a beam configured to support the component placed between the rounded end and the fastening end. The rounded end of the bracket is sized and shaped to fit in an enclosure of the encasement and to pivot about the pin during a rework process. Methods for installing and reworking the low profile hinge and pin mount are described.

### FIELD OF THE DESCRIBED EMBODIMENTS

The described embodiments relate generally to devices and methods for providing a supportive mount inside a housing. More specifically, embodiments describe devices and methods for providing a low profile mount assembly within a small housing, such as housing for a small electronic device.

### BACKGROUND

A trend in technology is to provide portable electronic devices, such as media players and mobile phones, which are easier for consumers to understand and use. This means providing smarter devices that involve more features and more complex inner workings. At the same time, consumers demand that the portable electronic devices be small and sturdy.

With the advent of ever smaller electronic devices coupled with an increase in a number of operational components, any unwise use of available space can result in poor designs. Moreover, as the number of components increase and the amount of volume decreases, assembly of these devices has become more difficult especially with regard to attaching and securing components. Furthermore, as the complexity of these devices increases and the assembly more difficult, the possibility of reworking non-compliant assemblies becomes more of an issue.

Therefore, what is desired are systems and methods for providing resilient structures for supporting electronic components and which occupy minimal space within a small enclosure.

### SUMMARY OF THE DISCLOSURE

This paper describes various embodiments that relate to systems and methods for providing a supportive mount within a small enclosure. Embodiments can be used, for example, for mounting electronic components within an electronic device, such as a portable media player or mobile phone. The mount is designed to be small and in particular to have a low profile so as to minimize space taken within the housing of the electronic component. The mount is designed to be sturdy so as to withstand forces placed upon it during normal use of the electronic device. In described embodiments, the mount has a hinge and pin to allow rotation of the mount along the axis of a pin useful, for example, in a rework or reassembly process.

In the described embodiments, the low profile mount includes a bracket and a pin. The bracket includes a first rounded end, a second fastening end and a beam portion disposed between the first rounded end and the second fastening end. The beam portion is configured to directly support a component. The first rounded end has a curved exterior surface that conforms to a curved interior surface of the housing. The second fastening end is configured to receive a fastener, the fastener used to secure the second fastening end directly to the housing. The pin includes a cylindrical body that engages an interior surface of the first rounded end at a pivot line about which the bracket rotates while in a rework configuration to provide ready access to the component. In a secured configuration, the interior surface of the rounded end can engage with the pivot line of the cylindrical body of the pin.

The described embodiments include an electronic device that includes at least a low profile system which includes a bracket, a pin, a switch and a button. The bracket has a rounded end, a fastening end and a beam, wherein the rounded end has a curved exterior surface with a size and shape to match with a curved interior surface of an interior surface of the housing for the electronic device. The pin is secured to the housing and includes a cylindrical body with a size and shape to match with a curved interior surface of the rounded end of the bracket. The curved interior surface of the rounded end pivots along a pivot line of the cylindrical body when in a rework configuration and engages with the pivot line when in a secured configuration. The switch is disposed on top of the beam between the rounded end and the fastening end. The button is positioned above and is configured to interact with the switch. The button is coupled to the housing such that a portion of the button is exposed at the exterior of the device such that a user can press the button. The low profiled mount system is configured to support the weight of the switch and a force placed upon the button by the user.

Methods described herein include a method for installing a hinge and pin mount assembly in a housing. The method includes positioning a rounded end of a bracket in a corresponding curved portion of the housing such that a cavity at the rounded end is roughly centered with a first and second opening in the enclosure. Next, a fastening end of the bracket is fastened to the housing by disposing a fastener in a hole of the fastening end of the bracket in a loose manner such that there is a clearance between the fastening end and the housing. Then, a force is provided along a beam of the bracket such that the cavity at the rounded end of the bracket is centered with the first and second openings in the housing such that a cylindrical pin can be placed therethrough. The cylindrical pin is then inserted thought the first opening and in alignment with the second opening. Next, the first end of the cylindrical pin is pressed to fully insert and engage the first and second ends of the cylindrical pin in the first and second openings in the housing, respectively. Finally, the fastener is tightened to fasten the fastening end to the housing. In this manner, the hinge in pin mount is assembled to a secured configuration.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIGS. 1A and 1B illustrate isometric and section views of a conventional bracket and screw system.

FIGS. 2A and 2B illustrate isometric and section views of a conventional bracket and countersink screw system.

FIGS. 3A and 3B illustrate isometric and section views of a hinge and pin mount system in accordance with described embodiments.

FIG. 4 illustrates a side view of a hinge and pin mount system installed in a housing in accordance with described embodiments.

FIG. 5 illustrates an isometric bottom view of a hinge and pin mount system installed in a housing in accordance with described embodiments.

FIG. 6 illustrates a bottom view of a hinge and pin mount system installed in a housing in accordance with described embodiments.

FIGS. 7A and 7B illustrate side views of a hinge and pin mount in secured and rework configuration, respectively, in accordance with the described embodiments.

FIG. 8 is a flowchart showing steps of an installation process of a hinge and pin mount system in accordance with described embodiments.

FIG. 9 is a flowchart showing steps of a rework process of a hinge and pin mount system in accordance with described embodiments.

### DETAILED DESCRIPTION OF EXAMPLE EMBODIMENTS

Representative applications of methods according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

The hinge and pin mount embodiments described herein provide a mechanism for supporting a component within an enclosure or housing of a small portable electronic device. The electronic device can take the form of a media player or mobile phone, for example. The hinge and pin mount is sturdy in that it can withstand the weight of the component placed thereon in addition to external forces such as pressure from a user pushing on external features of the electronic device. The hinge and pin mount is small, and in particular, has a low profile such that the hinge and pin mount resides close to the internal surface of the housing thereby maximizing the amount of space within the housing for other components, such as integrated circuits, cameras, batteries and printed circuit boards.

The low profile hinge can be well suited for electronic devices having many components packed into a small volume typical of hand held computing devices such as a smart phone such as the iPhone manufactured by Apple Inc. of Cupertino, Calif. The low profile hinge can provide a support for a component, such as a switch assembly, that can experience a large number of press events over an operating life of the electronic device. By providing a secure base upon which to support the switch, the switch can present a solid feel to a user indicative of a quality product. Furthermore, due to the complexity of an assembly operation used to manufacture the electronic device, the low profile hinge assembly can pivot about a pivot line to enable easy access to a component (such as the switch assembly) mounted to the low profile hinge assembly. The easy access can make any rework required to, for example, repair or replace the component easy and quick to perform. Accordingly, the low profile hinge assembly is described in accordance with the accompanying figures. It should be noted that although the low profile hinge assembly is described herein with respect to a portable media device, that the low profile hinge assembly is well suited for any situation where cost and time efficient assembly and rework is desirable.

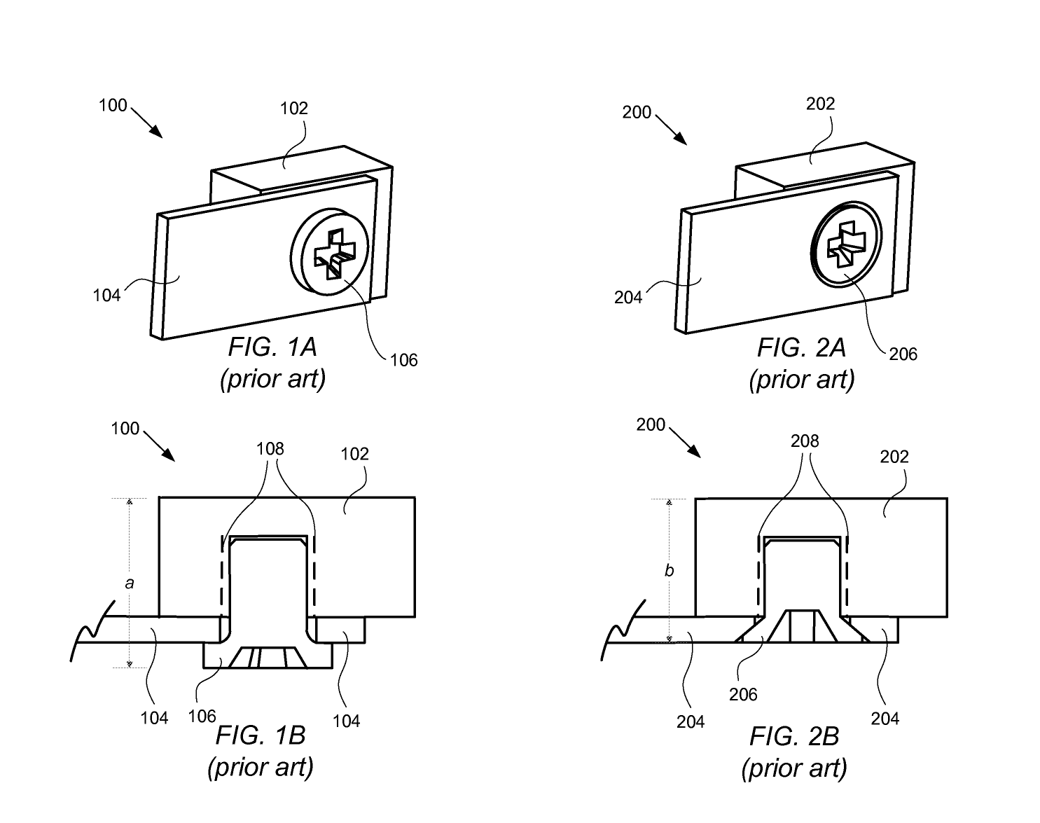

FIGS. 1A and 1B illustrate isometric and section views, respectively, of a conventional bracket and screw assembly 100. As shown, bracket 104 is coupled to structure 102 by screw 106. Due to the stack thickness a, conventional bracket and screw assembly 100 can take up a relatively large amount of space inside a small enclosure such as that for a small portable electronic device. In addition, a force placed upon bracket 104 by, for example, by external pressure placed on bracket 104, will be supported by threads 108 which hold screw 106 and bracket 104 to structure 102. Thus, pressure placed upon bracket 104 can strip threads 108 and destroy assembly 100.

FIGS. 2A and 2B illustrate isometric and section views, respectively, of an alternative conventional bracket and screw assembly 200. As shown, bracket 204 is coupled to structure 202 by screw 206. Screw 206 is countersunk in bracket 204, thereby reducing the stack thickness to a stack thickness b which is smaller than stack thickness a of conventional bracket and screw assembly 100. However, conventional bracket and screw assembly 200 can still take up a relatively large amount of space for a small enclosure such as a small portable electronic device. As with assembly 100, a force placed upon bracket 204 will be supported by threads 208 which hold screw 206 and bracket 204 to structure 202. Thus, pressure placed upon bracket 204 can strip threads 208 and destroy assembly 200.

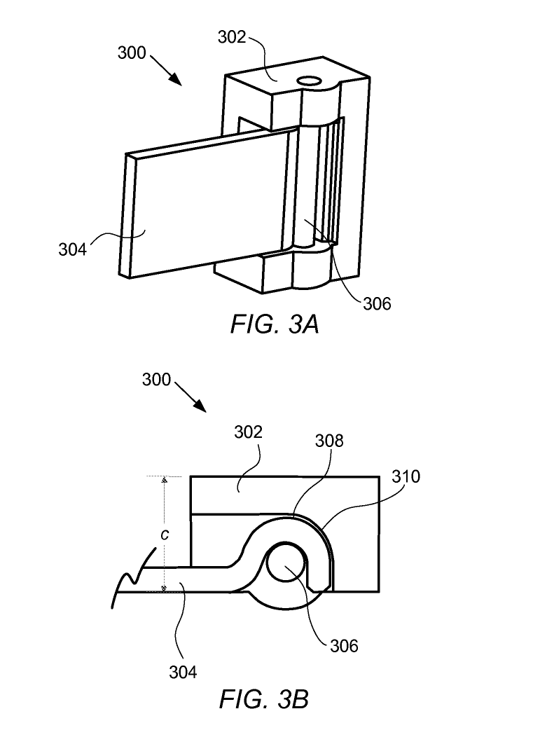

FIGS. 3A and 3B illustrate isometric and section views, respectively, of hinge and pin mount assembly 300 in accordance with embodiments described herein. As shown, bracket 304 has rounded end 308 which is shaped and sized to fit within curved portion 310 of structure 302. The interior surface of rounded end 308 is shaped and sized to fit pin 306 therein, such that pin 306 fits in the cavity formed within the interior surface of rounded end 308. In one embodiment, pin 306 can be about 0.6 mm in diameter and the interior surface of rounded end 308 can be about 0.7 mm in diameter. Hinge and pin mount assembly 300 has a stack thickness c, which leaves adequate room within a small enclosure, such as a portable electronic device housing, for additional components. A force placed upon bracket 304 by, for example, the weight of a component placed on bracket 304 and external pressure placed on bracket 304, can be supported by pin 306 where it is coupled to structure 302.

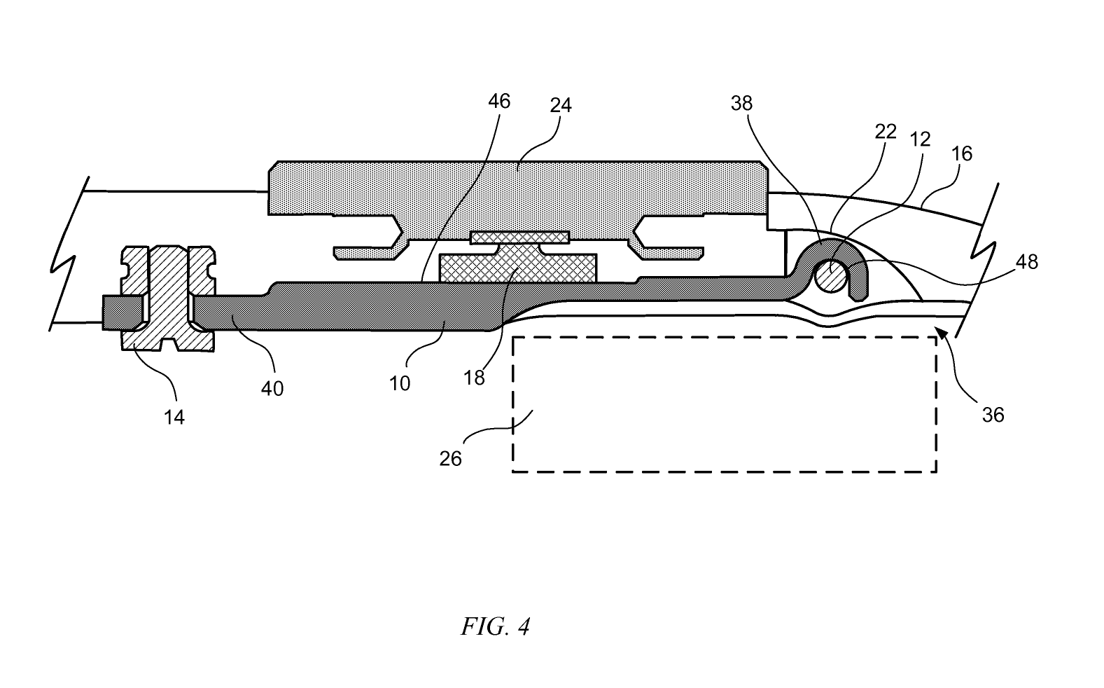

FIG. 4 illustrates a side section view of a hinge and pin mount assembled within a housing, such as the housing for an electronic device, in accordance with described embodiments. Bracket 10 can be situated in housing 16 at rounded end 38 by pin 12 and at fastening end 40 by fastener 14. Fastener 14 can be a screw and nut assembly, as shown in FIG. 4, wherein fastener 14 is disposed in an opening of the fastening end of the bracket. Any suitable fasteners can be used such as a press fit or welded assembly. In one embodiment, an additional hinge and pin mount assembly can be used to fasten the fastening end 40 of bracket 10. The rounded end 38 of bracket 10 can be sized and shaped to fit in a curved portion 22 of an enclosure of housing 16. The interior surface of rounded end 38 forms a cavity 48 which can be sized and shaped to fit cylindrical pin 12 therein. Component 18 can be positioned on top of beam 46 portion of bracket 10. Beam 46 is disposed between rounded end 38 and fastening end 40 of bracket 10. Component 18 can be any suitable component or fixture. In this case, component 18 can be a switch which is configured to interact with button 24 that is coupled with housing 16. Button 24 can have an exterior surface which is exposed at the exterior of the device. When button 24 is pressed from the exterior surface, such as by a user of the device, component 18 can be activated. In addition, the device can get dropped and fall on button 24. As button 24 is pressed, a force is place upon component 18, and in turn, upon bracket 10. Thus, bracket 10 is configured to withstand the weight of component 18 as well as a force placed upon button 24. Bracket 10 can be made of any suitable material for providing adequate strength to withstand pressures described above. For example, bracket 10 can be fabricated from a metal such as steel (e.g., 304 stainless steel) or aluminum, or it can be fabricated of a non-metallic material such as a polymer or ceramic material. It should be noted that bracket 10 can experience some bending when force is applied thereon, which can be a factor for considering appropriate materials for fabricating bracket 10.

The cross section or profile of hinge and pin mount assembly of FIG. 4 is thin and conforms closely to the internal surface of housing 16, thereby providing room for element 26 positioned at a distance 36 below bracket 10. In a typical portable electronic device, element 26 can be any suitable electronic component such as an integrated circuit, camera or battery. Since the hinge and pin mount of FIG. 4 has a low profile, distance 36 can be larger when compared to conventional mounting assemblies. Since bracket 10 can experience a certain amount of bending depending on the materials used, the amount of displacement of bracket 10 during bending can be considered when determining distance 36 for positioning element 26 below bracket 10. Another consideration in determining distance 36 is possible electromagnetic interference. For example if bracket 10 is manufactured from metal materials, element 26 can be positioned at a larger distance 36 to provide more of a capacitive separation between element 26 and bracket 10, which can result in better antenna performance of element 26.

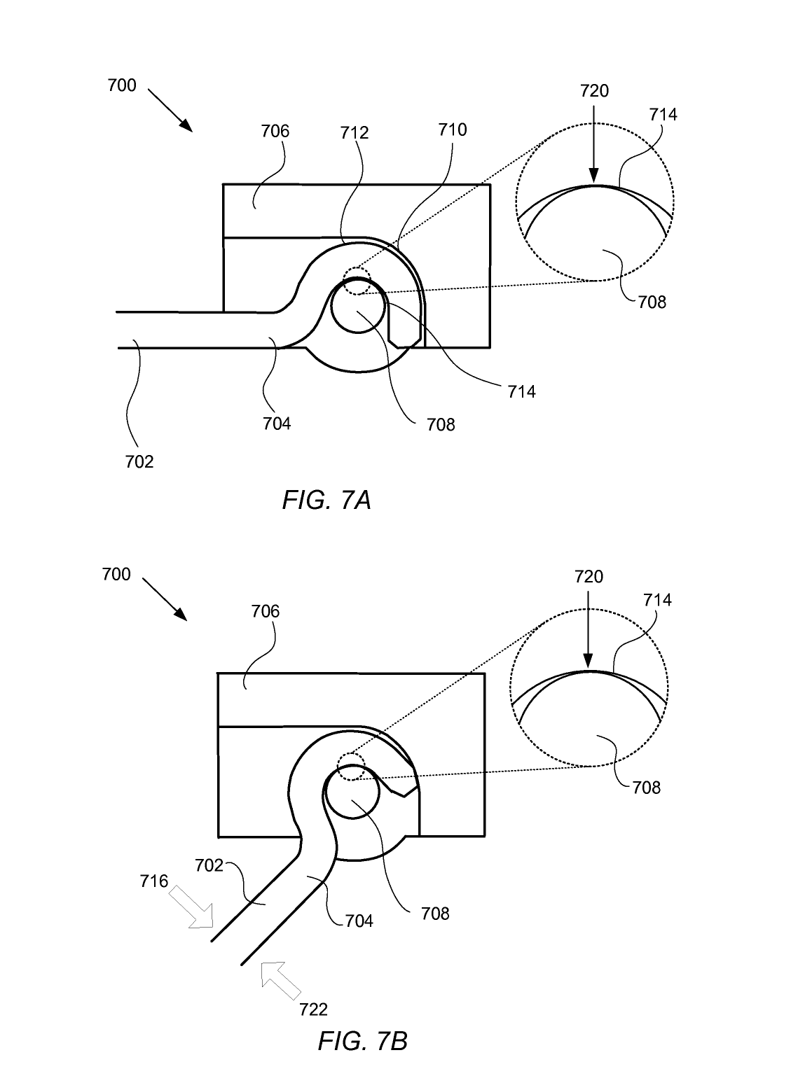

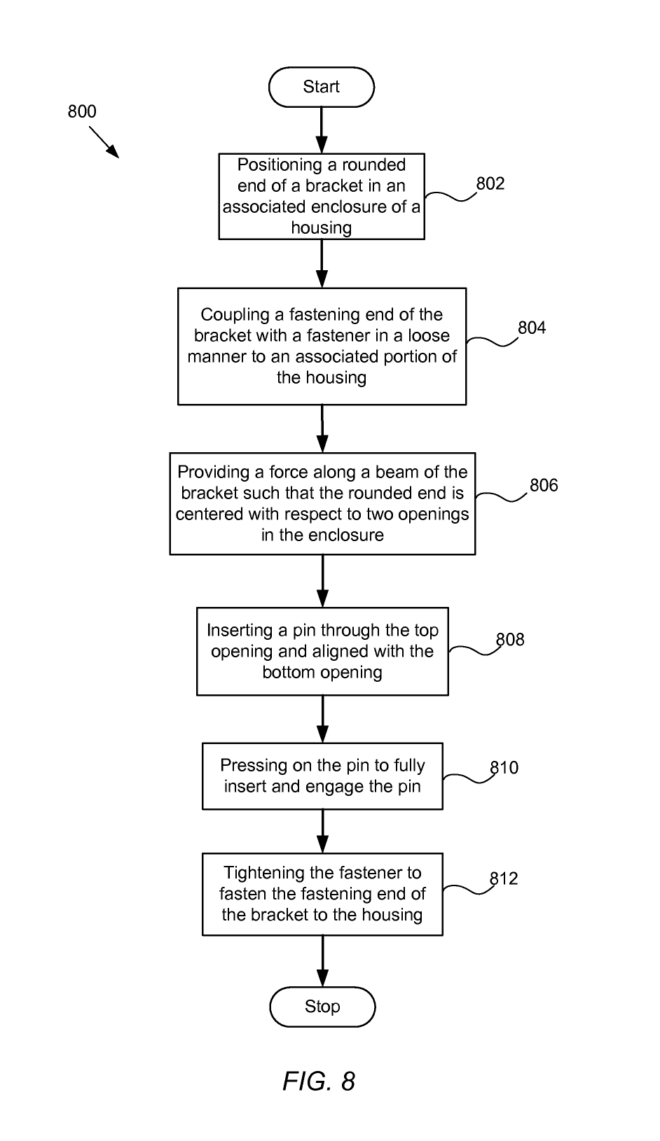

A useful feature of the hinge and pin mount shown in FIG. 4 is that fastener 14 can be removed from housing 16 to allow bracket 10 to pivot at its rounded end about pin 12, thereby allowing access to component 18 without fully disassembling the hinge and pin mount assembly. This feature can be useful, for example, during a rework or reassembly process wherein a component is removed for testing and replacement or the component is replaced with a new component. In some cases it can be desirable to add additional components. Embodiments of the hinge and pin mount described herein allow easy and quick access to component 18 situated on top of bracket 10 during such a rework or reassembly process. In addition, since during a rework process pin 12 can remain in place without removal, there can be less interference with other components residing within housing. Details about embodiments of a rework or reassembly process will be described below with reference to FIGS. 7A and 7B.

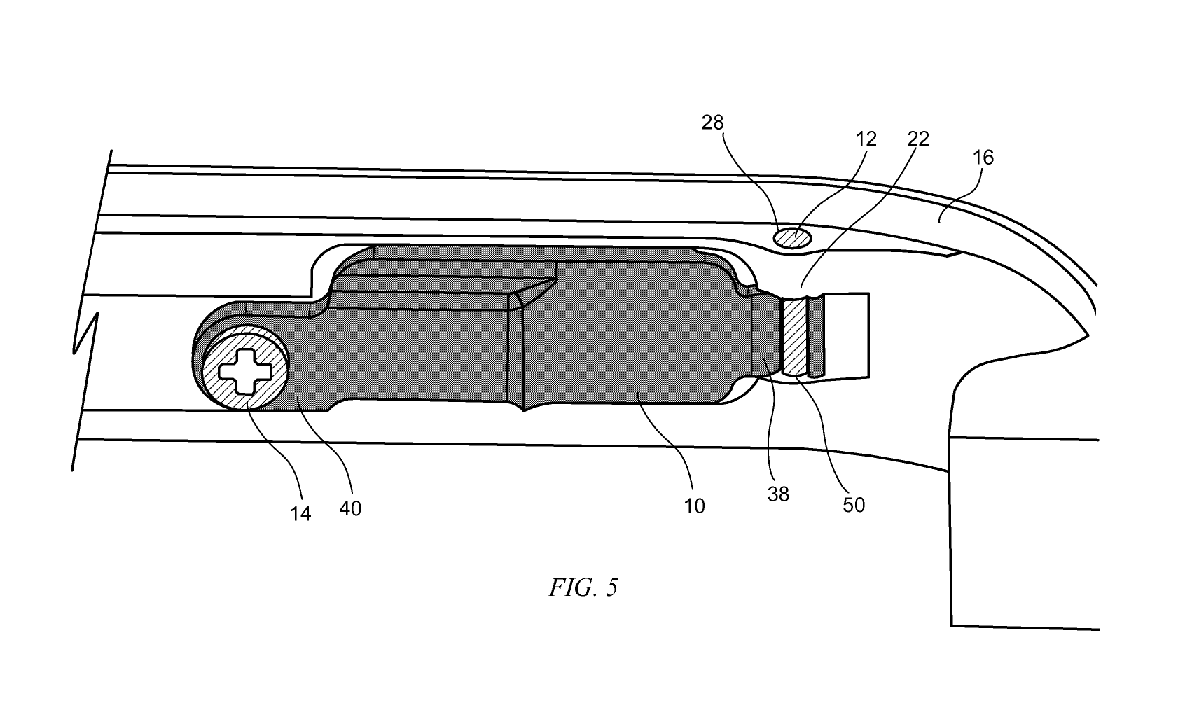

FIG. 5 illustrates an isometric bottom view of a hinge and pin mount assembled in a housing in accordance with described embodiments. As shown, housing 16 is configured to have a curved enclosure 22 for placing rounded end 38 of bracket 10 therein. Curved enclosure 22 has a top opening 28 and a bottom opening 50 configured to fit the ends of pin 12 therein. Bracket 10 can be coupled to housing 16 at fastening end 40 using screw 14 and nut (not shown). Note that any suitable fastening device can be used to fasten fastening end 40 to housing 16, including another hinge and pin mount assembly. Note that bracket 10 can be significantly recessed within housing 16, especially at curved enclosure 22 portion such that bracket 10 is almost flush with the interior surface of housing 16, thereby maximizing the amount of space within housing 16 for electronic components. A component such as a switch (not shown) can be positioned on the top of bracket 10, which can in turn be configured to interact with a button (not shown) on the exterior of housing 16.

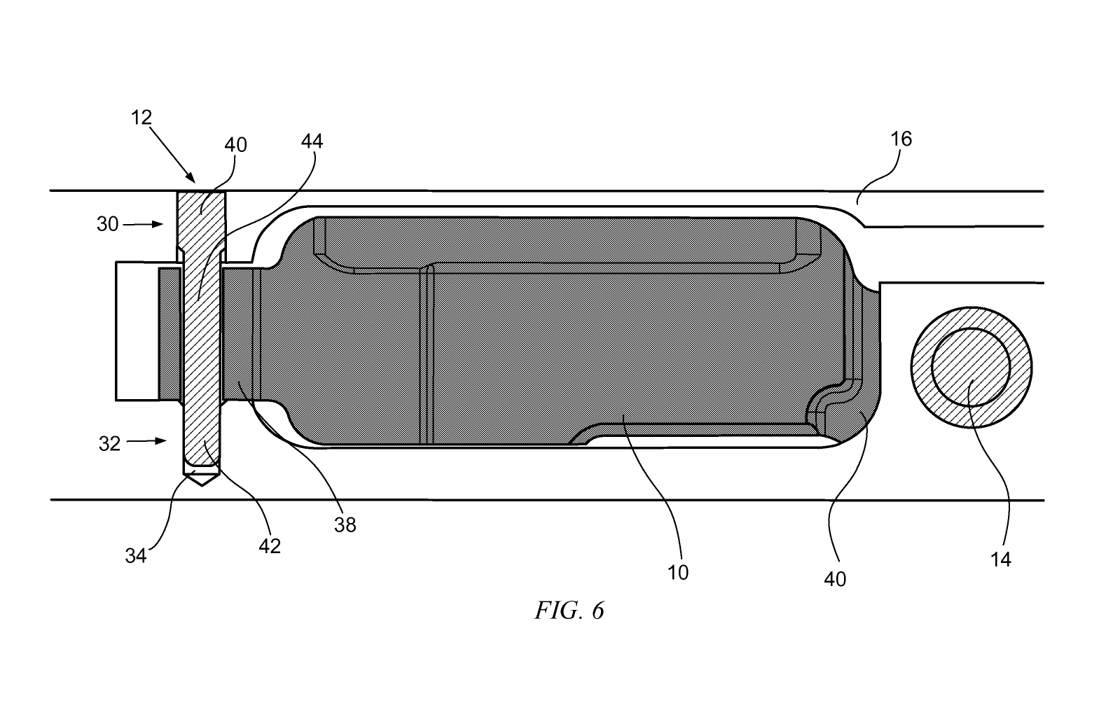

FIG. 6 illustrates a bottom view of a hinge and pin mount assembled in a housing in accordance with described embodiments. Bracket 10 is situated in housing 16 at rounded end 38 by pin 12 and at fastening end 40 by fastener 14. Pin top 40 can be configured to fit in top opening 30 and pin bottom 42 can be configured to fit in bottom opening 32 of housing 16. Pin body 44 is cylindrical in shape such that rounded end 38 of bracket 10 can pivot about pin 12. In the embodiment shown, pin top 40 has a bigger diameter than pin bottom 42, thus top opening 30 is larger than bottom opening 32. In one embodiment, pin top 40 is 0.8 mm in diameter and pin bottom 42 and body 44 are 0.6 mm in diameter. In other embodiments, the pin top 40 and pin bottom 42 are of the same diameter and top opening 30 and bottom opening 32 are of the same diameter. Pin 12 can be configured to be press fit into openings 30 and 32, using for example a press fit compressor tool. In other embodiments, pin top 40 and pin bottom 42 can be non-cylindrically shaped. For example, pin top 40 and pin bottom 42 can be square or octagonal in shape, with correspondingly shaped top opening 30 and bottom opening 32.

In FIG. 6, a hinge and pin mount in accordance with embodiments is fully installed and in a secured configuration such that component (not shown) position on the top of bracket 10 is fully supported. FIG. 6 shows the hinge and pin mount in a secured configuration such that pin 12 is fully press fit into top 30 and bottom 32 openings. A clearance 34 can be provided below the pin bottom 42 so that pin bottom 42 does not bottom out in bottom opening 32. In some embodiments, bottom opening 32 can be a hole that fully goes through housing 16. Although in the shown embodiment, pin 12 is configured to be press fit in housing 16, other configurations can be used. For example, pin 12 can be configured to have threads to threadably engage with one or both of top 30 and bottom 32 openings. Alternatively, pin 12 can be configured to couple with housing 16 using a welding, brazing or soldering method.

As discussed above, the hinge and pin mount embodiments described herein can be used to access component(s) placed thereon during a reassembly or rework process. FIGS. 7A and 7B illustrate side views of a portion of hinge and pin mount 700 in secured and rework configurations, respectively, in accordance with the described embodiments. In FIG. 7A, hinge and pin mount 700 has bracket 702 with exterior surface 712 of rounded end 704 configured to fit in a curved portion 710 of an enclosure of housing 706. Interior surface 714 of rounded end 704 is configured to fit around at least a portion of the outside surface of cylindrical pin 708. As shown in the inset of FIG. 7A, the weight of bracket 702 and any component and force placed thereon, is supported by pin 708 where internal surface 714 contacts pin 708. This contact area can be referred to as a pivot line 720.

FIG. 7B shows hinge and pin mount 700 in a rework configuration such that a component (not shown) positioned on bracket 702 can be accessed. First, the fastening end (not shown) of bracket 702 is unfastened so that the fastening end of bracket 702 is uncoupled from the housing 706. Next, a force 716 is placed upon bracket 702 such that rounded end 704 pivots about pin 708 along pivot line 720 of pin 708, thereby providing access to the top of bracket 702. After access to the top of bracket 702 is no longer needed, force 722 is placed upon bracket 702 such that interior surface 714 of bracket 702 pivots about pin 708 along pivot line 720 of pin 708 and the fastening end of bracket is positioned for re-fastening to housing 706. Finally, a fastener is used to couple the fastening end of bracket 702 to housing 706. The hinge and pin mount 700 is once again in a secured configuration.

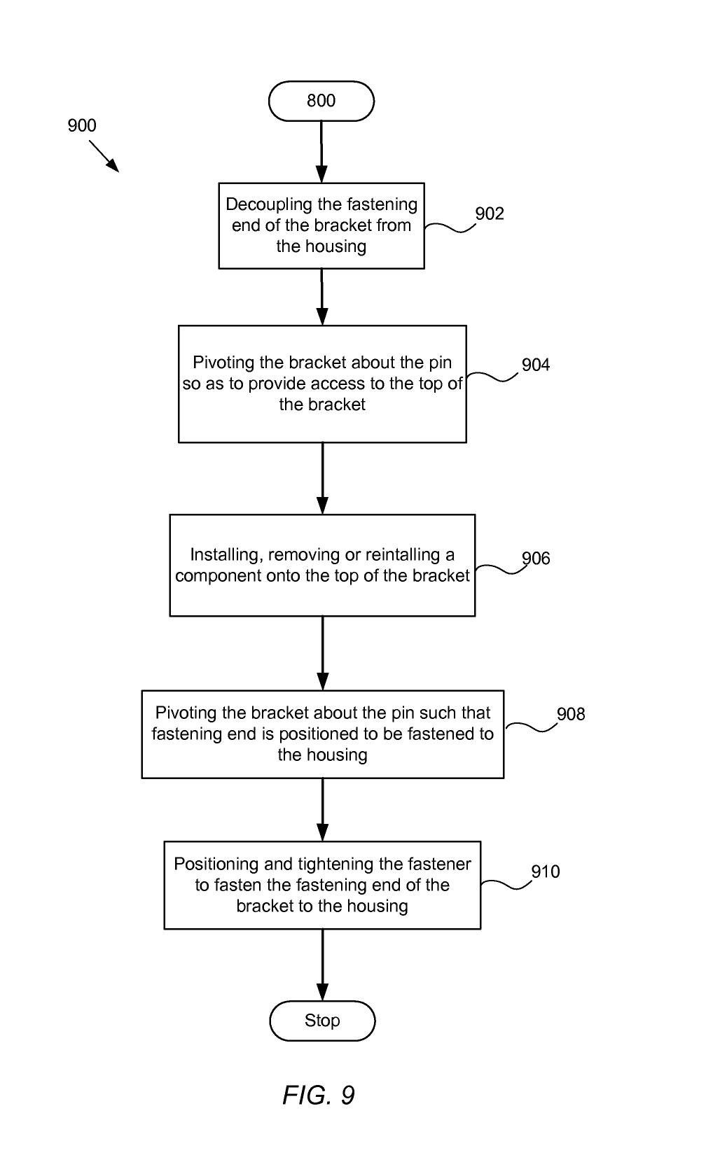

FIGS. 8 and 9 are flowcharts showing steps of an installation and a rework process, respectively, of a hinge and pin mount in accordance with described embodiments. In FIG. 8, installation process 800 starts at 802 wherein a rounded end of a bracket is positioned in an associated curved enclosure of a housing such that a cavity created by the internal surface of the rounded end is roughly aligned with a top and a bottom openings of the enclosure. At 804, the fastening end of the bracket is coupled to the housing in a loose manner such that a clearance is provided between the fastening end of the bracket and the housing. At 806, a force is provided along the beam of the bracket such that the cavity of the rounded end is fully aligned with the top and bottom openings of the enclosure. At 808, a pin is inserted though the top opening and aligned with the bottom opening. This is to assure that the bottom of the pin is properly aligned with the bottom opening before pressure is applied to the pin. At 810, pressure is placed on the pin to fully insert and engage the pin in a press fit manner. At 812, the fastener is tightened at the fastening end of the bracket to tightly couple the fastening end to the housing. The hinge and pin mount is then in a secured configuration wherein any component or force placed on the beam of the bracket is fully supported.

In FIG. 9, rework process 900 starts after the installation process 800 is complete. As described previously, a rework process allows access to the top of the bracket after the hinge and pin mount has already been installed. This can be done, for example, to place or remove a component positioned on top the bracket. At 902, the fastening end of the bracket is decoupled from the housing by loosening and removing the fastener. At 904, the bracket is pivoted about the pin by placing a force along the beam such that the top of the beam can be accessed. At 906, a component can be installed, removed or reinstalled to or from top of the bracket. At 908, the bracket is pivoted about the pin by placing a force along the beam such that the fastening end is positioned to be fastened to the housing. At 910, the fastener is positioned and tightened to fasten the fastening end to the housing. The hinge and pin mount is then in once again in a secured configuration.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A low profile mount assembly for supporting a component in a housing, comprising:
a bracket, the bracket comprising:
a first rounded end, the first rounded end having a curved exterior surface that conforms to a curved interior surface of the housing;
a second fastening end configured to receive a fastener, the fastener used to secure the second fastening end directly to the housing; and
a beam portion disposed between the first rounded end and the second fastening end, the beam portion configured to directly support the component; and
a pin secured to the housing, the pin comprising a cylindrical body that engages an interior surface of the first rounded end at a pivot line about which the bracket rotates in a rework configuration to provide ready access to the component.

2. The low profile mount assembly as recited in claim 1, wherein the interior surface of the rounded end engages with the pivot line of the cylindrical body of the pin when in a secured configuration.

3. The low profile mount assembly as recited in claim 1, wherein the fastener includes a screw and nut assembly configured to fit in an opening of the fastening end of the bracket.

4. The low profile mount assembly as recited in claim 1, wherein the pin has a first end adapted to couple with a first opening of the enclosure and a second end adapted to couple with a second opening in the enclosure.

5. The low profile mount assembly as recited in claim 5, wherein the first end has a larger diameter than the second end.

6. The low profile mount assembly as recited in claim 5, wherein the first and second ends are press fit into the first and second opening, respectively.

7. The low profile mount assembly as recited in claim 1, wherein the component is a switch.

8. The low profile mount assembly as recited in claim 7, further comprising a button disposed on enclosure wherein the button is configured to interact with the switch positioned beneath the button.

9. The low profile mount assembly as recited in claim 1, further comprising an element positioned adjacent to the low profile mount assembly and housed within the enclosure.

10. The low profile mount assembly as recited in claim 9, wherein the element is one of a camera, battery or integrated circuit.

11. The low profile mount assembly as recited in claim 10, wherein the element is positioned a suitable distance away from the low profile mount to minimize electromagnetic interference.

12. A method of installing a mount assembly in a housing, the mount assembly having a bracket, a cylindrical pin and a fastener, the method comprising:
positioning a rounded end of the bracket in a curved portion of the housing such that a cavity at the rounded end is roughly centered with a first and second opening in the enclosure;
coupling a fastening end of the bracket to the housing by disposing a fastener in a hole of the fastening end of the bracket in a loose manner such that there is clearance between the fastening end and the housing;
providing a force along a beam of the bracket such that the cavity at the rounded end of the bracket is centered with the first and second openings in the housing such that the cylindrical pin can be placed therethrough;
inserting the cylindrical pin though the first opening and in alignment with the second opening;
pressing on a first end of the cylindrical pin to fully insert and engage the first end of the cylindrical pin in the first opening and the second end of the cylindrical pin in the second opening; and
tightening the fastener in the fastening end of the bracket to the housing, thereby placing the mount assembly in a secured configuration.

13. The method as recited in claim 4, further comprising a rework process, the rework process comprising:
removing the fastener from the fastening end of the bracket thereby decoupling the fastening end of the bracket from the housing;
pivoting the bracket such that a curved interior surface of the rounded end pivots along a pivot line of the cylindrical pin, thereby giving access to a top surface of the bracket; and
placing, removing or replacing a component from the top surface of the bracket.

14. The method as recited in claim 13, further comprising:
pivoting the bracket such that the fastening end is positioned to be fastened to the housing; and
refastening and tightening the fastening end to the housing, thereby placing the mount assembly in a secured configuration.

15. An electronic device comprising a low profile mount system, low profile mount system comprising:
a bracket having a curved end, a fastening end and a beam, wherein the rounded end has an rounded exterior surface with a size and shape to match with a curved interior surface of the a housing for the electronic device;
a pin secured to the housing, the pin comprising a cylindrical body with a size and shape to match with a curved interior surface of the rounded end of the bracket, wherein the curved interior surface pivots along a pivot line of the cylindrical body when in a rework configuration, and wherein the curved interior surface engages with the pivot line of the cylindrical body when in a secured configuration;
a switch disposed on the top surface of the beam between the rounded end and the fastening end; and
a button positioned above and configured to interact with the switch, wherein the button is coupled to the housing such that a portion of the button is exposed at the exterior of the device such that a user can press the button, and wherein the low profiled mount system is configured to support the weight of the switch and a force placed upon the button by the user.

16. The electronic device of claim 15, wherein the fastening end is coupled to the housing in the secured configuration by a fastener disposed in an opening of the fastening end of the bracket.

17. The electronic device as recited in claim 16, wherein the fastener includes a screw and nut assembly.

18. The electronic device as recited in claim 15, further comprising an element positioned adjacent to the rounded end of the bracket and housed within the enclosure.

19. The electronic device as recited in claim 18, wherein the element is one of a camera, battery or integrated circuit.

20. The electronic device as recited in claim 19, wherein the element is positioned a suitable distance away from the rounded end of the bracket to minimize electromagnetic interference.
